(19) United States
(12) Patent Application Publication
(10) Pub. No.: US 2011/0284923 A1
(43) Pub. Date: Nov. 24, 2011

(54) SEMICONDUCTOR DEVICE AND MANUFACTURING METHOD OF THE SAME

(75) Inventor: Shuji KAMATA, Hyogo-ken (JP)

(73) Assignee: Kabushiki Kaisha Toshiba, Tokyo (JP)

(21) Appl. No.: 13/051,984

(22) Filed: Mar. 18, 2011

(30) Foreign Application Priority Data
May 21, 2010 (JP) 2010-117217

(51) Int. Cl. H01L 29/739; H01L 21/331

(52) U.S. Cl. 257/139; 438/138; 257/E29.197; 257/E21.382

(57) ABSTRACT

A semiconductor device includes: a first semiconductor region; a second semiconductor region provided on a first major surface of the first semiconductor region; a first major electrode; a third semiconductor region provided in a part of a third major surface of the second semiconductor region; a fourth semiconductor region provided in a part of a fourth major surface of the third semiconductor region; a second major electrode; a control electrode; a fifth semiconductor region; and a sixth semiconductor. The fifth semiconductor region is provided passing through the fourth semiconductor region along a direction perpendicular to the fourth major surface of the third semiconductor region. The sixth semiconductor region is provided in contact with a bottom part of the fourth semiconductor region, and has a higher impurity concentration than the third semiconductor region.

### CROSS-REFERENCE TO RELATED APPLICATIONS

This application is based upon and claims the benefit of priority from the prior Japanese Patent Application No. 2010-117217, filed on May 21, 2010; the entire contents of (all of) which are incorporated herein by reference.

### FIELD

Embodiments described herein relate generally to semiconductor device and manufacturing method of the same.

### BACKGROUND

A semiconductor device such as a vertical power MOSFET (Metal-Oxide-Semiconductor Field-Effect Transistor), an IGBT (Insulated Gate Bipolar Transistor), and an IEGT (Injection Enhanced Gate Transistor) includes a parasitic transistor in a MOS region because of the structure thereof. Usually, the base and the emitter of the parasitic transistor are shorted, and as a result the device is designed so that the parasitic transistor do not operate. When a large current flows, however, a base potential is increased through a base resistance and a forward bias is applied across the base and the emitter. Therefore, the parasitic transistor becomes turned on. When the parasitic transistor is turned on, current cannot be controlled by a gate voltage due to thyristor action (hereinafter, called latch-up).

Accordingly, in order to reduce the base resistance as low as possible, there is devised a configuration of providing a low resistance layer for carrier extraction which has a resistance value in a range without affecting a threshold value. In a planar-gate type IGBT or IEGT, a carrier extraction layer is introduced in the center of an active cell and intended to reduce the base resistance in the bottom part of an emitter layer by side diffusion. However, when the side diffusion is not uniform, the threshold value is affected and thus the base resistance in the bottom part of the emitter layer cannot be reduced enough. Accordingly, there is a room for improving a withstand strength with respect to the latch-up of the semiconductor device.

### BRIEF DESCRIPTION OF THE DRAWINGS

FIG. 1 is a schematic cross-sectional view illustrating a configuration of a semiconductor device according to a first embodiment;

FIG. 2 is a schematic cross-sectional view enlarging a part of the semiconductor device according to the first embodiment;

FIGS. 3A and 3B are schematic diagrams illustrating an entire configuration of the semiconductor device according to the first embodiment;

FIGS. 4A to 7B are schematic diagrams sequentially explaining the manufacturing method of the semiconductor device according to the second embodiment;

FIG. 8 is a schematic cross-sectional view illustrating a configuration of a semiconductor device according to a third embodiment;

FIG. 9 is a schematic perspective view illustrating a configuration of a semiconductor device according to a fourth embodiment; and

FIG. 10 is a schematic perspective view illustrating a configuration of a semiconductor device according to a fifth embodiment.

### DETAILED DESCRIPTION

In general, according to one embodiment, a semiconductor device includes: a first semiconductor region; a second semiconductor region provided on a first major surface of the first semiconductor region; a first major electrode; a third semiconductor region provided in a part of a third major surface of the second semiconductor region; a fourth semiconductor region provided in a part of a fourth major surface of the third semiconductor region; a second major electrode; a control electrode provided; a fifth semiconductor region; and a sixth semiconductor. The fifth semiconductor region is provided passing through the fourth semiconductor region along a direction perpendicular to the fourth major surface of the third semiconductor region. The sixth semiconductor region is provided in contact with a bottom part of the fourth semiconductor region, and has a higher impurity concentration than the third semiconductor region.

According to another embodiment, a manufacturing method of a semiconductor device includes: forming a first semiconductor region of a first conductivity type; forming a second semiconductor region of the first conductivity type on a first major surface of the first semiconductor region; forming an insulating film in a third major surface of the second semiconductor region, the third major surface being opposite to the first semiconductor region; introducing impurities via the insulating film and forming a third semiconductor region of a second conductivity type selectively in the third major surface of the second semiconductor region; forming a groove in the insulating film and the third semiconductor region in a direction perpendicular to the third major surface of the second semiconductor region; introducing impurities into the third semiconductor region via the groove and forming a sixth semiconductor region having a higher impurity concentration than the third semiconductor region so as to cause the sixth semiconductor region to contact a bottom part of the groove; forming a semiconductor layer on the groove and the insulating film, and then introducing impurities into the semiconductor layer to provide conductivity thereto and also forming a fourth semiconductor region of the first conductivity type in the third semiconductor region neighboring the groove; separating the semiconductor layer on the insulating film and the semiconductor layer within the groove from each other and forming the semiconductor layer on the insulating film as a control electrode and forming the semiconductor layer within the groove as a fifth semiconductor region of the first conductivity type; forming a first major electrode on a second major surface side of the first semiconductor region, the second major surface being opposite to the first major surface; and connecting a second major electrode to the third semiconductor region and the fourth semiconductor region.

Hereinafter, embodiments of the invention will be explained according to the drawings.

Note that the drawing is schematic or conceptual and a relationship between the thickness and the width of each part, a proportionality coefficient of a size between the parts, and the like are not always the same as those in an actual case. Furthermore, even when the same part is shown, the size and the proportionality coefficient are sometimes shown differently depending on the drawing.

Moreover, in this specification and each of the drawings, an element similar to that described previously with respect to a previously shown drawing is denoted by the same numeral and detailed explanation will be omitted optionally.

In addition, the following explanation shows a specific example in which a first conductivity type is an n-type and a second conductivity type is a p-type, for example.

Furthermore, the following explanation will be made for an example of using silicon as a semiconductor.

Moreover, in the following explanation, a first direction, one of directions parallel to one major surface 11a of an n⁺ drain layer 11 (first semiconductor region), is defined as a Y direction. Then, a second direction perpendicular to the first direction (Y direction) among the directions parallel to the major surface 11a is defined as an X direction. Furthermore, a direction perpendicular to the major surface 11a is defined as a Z direction. In addition, a direction from the n⁺ drain layer 11 toward an n-type drift layer 12 (second semiconductor region) is defined as an up-direction (upper side) and the reverse direction is defined as a down-direction (lower side).

### First Embodiment

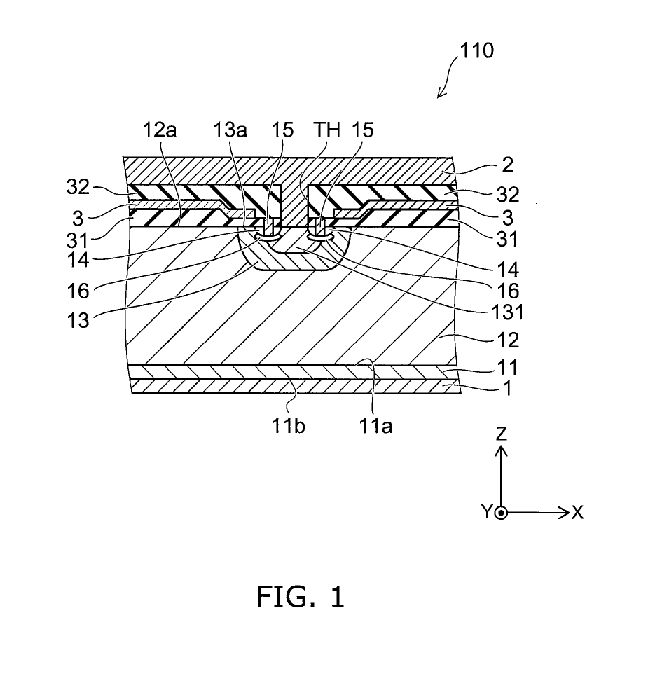

FIG. 1 is a schematic cross-sectional view illustrating a configuration of a semiconductor device according to a first embodiment.

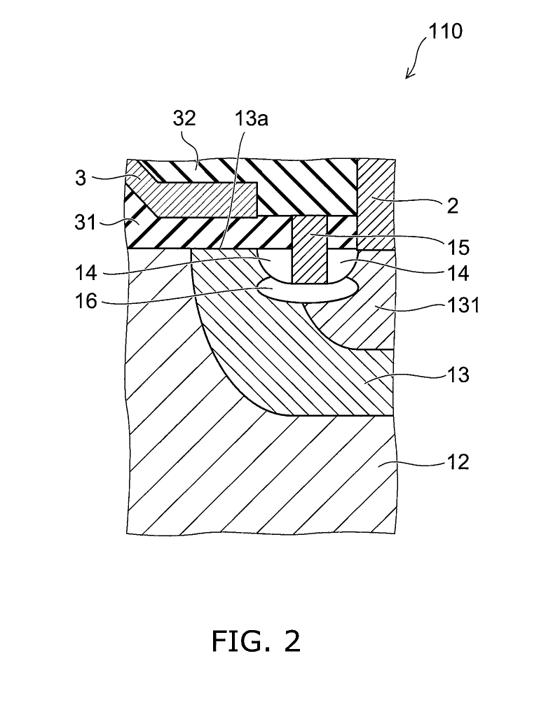

FIG. 2 is a schematic cross-sectional view enlarging a part of the semiconductor device according to the first embodiment.

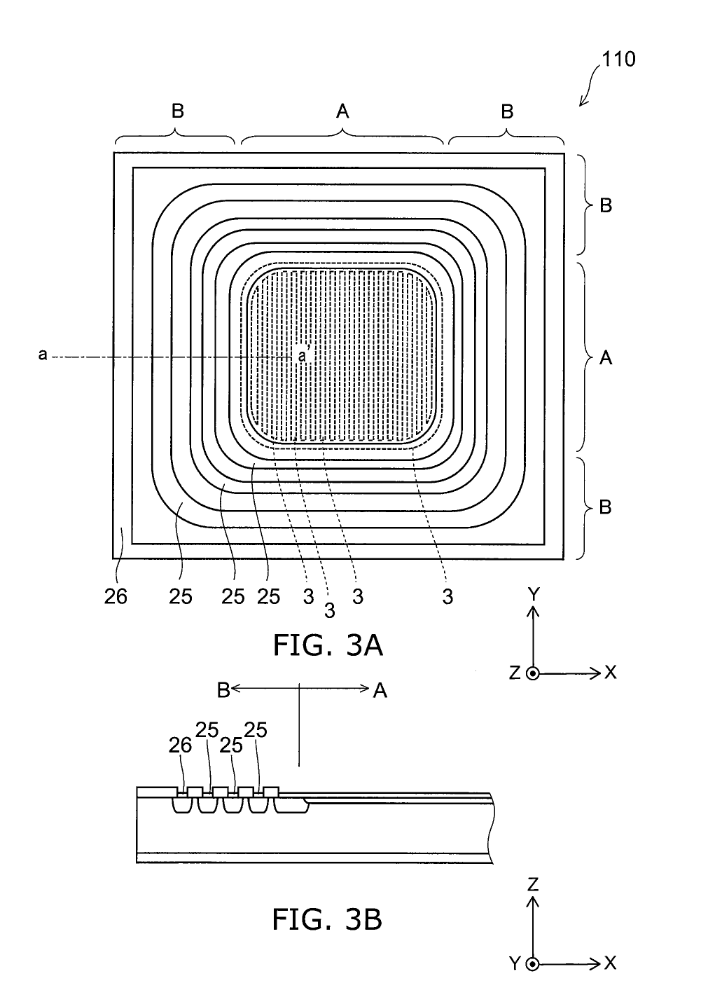

FIGS. 3A and 3B are schematic diagrams illustrating an entire configuration of the semiconductor device according to the first embodiment.

First, the entire configuration of the semiconductor device 110 according to the embodiment will be explained according to FIGS. 3A and 3B.

FIG. 3A is a schematic plan view of the semiconductor device 110, and FIG. 3B is a schematic cross-sectional view taken along the a-a′ line of FIG. 3A.

That is, as shown in FIGS. 3A and 3B, the semiconductor device 110 is provided with a cell region A in the central part, and a termination region B surrounding the outside of the cell region A. In the cell region A, plural gate electrodes 3 are formed each in the form of a stripe along the Y direction. Furthermore, the plural gate electrodes 3 are disposed at a predetermined interval along the X direction in the cell region A.

A guard-ring electrode 25 is provided in the termination region B. The guard-ring electrode 25 is provided so as to surround the periphery of the cell region A. The guard-ring electrode 25 is provided in a plural number as needed. An EQPR (Equivalent Potential Ring) electrode 26 is provided outside the outermost guard-ring electrode 25.

Next, according to FIG. 1 and FIG. 2, a cross-sectional structure of the semiconductor device 110 according to the embodiment will be explained. Note that explanation will be made as follows in accordance with the illustration of the cross-sectional structure centered between two neighboring gate electrodes 3.

As shown in FIG. 1, the semiconductor device 110 according to the embodiment functions as a vertical power MOS transistor.

That is, the semiconductor device 110 is provided with an n⁺ buffer layer (first semiconductor region) 11, an n-type drift layer (second semiconductor region) 12, a drain electrode (first major electrode) 1, a p-type base layer (third semiconductor region) 13, an n⁺ source layer (fourth semiconductor region) 14, a source electrode (second major electrode) 2, a gate electrode (control electrode) 3, a high-concentration n-type embedded layer (fifth semiconductor region) 15, and a p⁺ carrier extraction layer (sixth semiconductor region) 16.

The n-type drift layer 12 is provided on one major surface 11a of the n⁺ buffer layer 11. The other major surface 11b side of the n⁺ buffer layer 11 is provided with the drain electrode 1. The p-type base layer 13 is selectively provided for a major surface 12a of the n-type drift layer 12. The p-type base layer 13 is provided n the form of a stripe along a direction parallel to the major surface 12a of the n-type drift layer 12, for example.

In the center of a major surface 13a of the p-type base layer 13, a p⁺ layer 131 is provided as a part of the third semiconductor region. The p⁺ layer 131 plays a role of contacting the source electrode 2 to be described below. Each of the p-type base layers 13 on both outsides of this p⁺ layer 131 forms a channel of the MOS transistor.

The major surface 13a of the p-type base layer 13 is selectively provided with the n⁺ source layer 14. The two n⁺ source layers 14 illustrated in FIG. 1 are provided on both end parts of the p⁺ layer 131 in the p-type base layer 13, respectively. That is, the two n⁺ source layers 14 are provided along both end parts of the p⁺ layer 131, respectively. That is, each of the n⁺ source layers 14 provided on both sides of the p⁺ layer 131 is provided so as to contact the channel only one side. Furthermore, the p⁺ layer 131 is provided between the two n⁺ source layers 14. The source electrode 2 to be described below is connected to the p⁺ layer 131 disposed between the two n⁺ source layers 14.

The gate electrode 3 is provided via a gate insulating film 31 which covers the p-type base layer 13, the n⁺ source layer 14, and the n-type drift layer 12. FIG. 1 illustrates the neighboring two gate electrodes 3. Each of the gate electrodes 3 is disposed on the p-type base layer 13 between the n⁺ source layer 14 and n-type drift layer 12. Therefore, this part of the p-type base layer 13 functions as the channel. Here, each of the gate electrodes 3 has the same potential electrically.

The source electrode 2 is provided over the gate electrode 3 via an interlayer insulating film 32. The source electrode 2 is connected to the p-type base layer 13 between the two n⁺ source layers 14 via a through hole TH provided between the two gate electrodes 3.

In the central part of each of the n⁺ source layers 14, the high-concentration n-type embedded layer 15 is provided, passing through in the Z direction. The high-concentration n-type embedded layer 15 may be provided so as to pass through from the surface of the gate insulating film 31 to the bottom part of the n⁺ source layer 14.

Furthermore, the p-type base layer 13 contacting the bottom part of the n⁺ source layer 14 is provided with the p⁺ carrier extraction layer 16. The impurity concentration of the p⁺ carrier extraction layer 16 is higher than the impurity concentration of the p-type base layer 13.

As shown in FIG. 2, the high-concentration n-type embedded layer 15 passing through in the Z direction is provided in the central part of the n⁺ source layer 14. The p⁺ carrier extraction layer 16 is provided spreading from the bottom part of the n⁺ source layer 14, that is, the lower end part of the high-concentration n-type embedded layer 15, to the p-type base layer 13 and the p⁺ layer 131.

By providing such a p⁺ carrier extraction layer 16, it is possible to reduce a base resistance directly under the n⁺ source layer 14. As a result, a hole current path is formed when a large current flows, and the increase in the base potential is suppressed. Accordingly, the latch-up withstand strength is improved in the semiconductor device 110.

Further, the p⁺ carrier extraction layer 16 is disposed at a position apart from the channel formed in the p-type base layer 13. That is, the p⁺ carrier extraction layer 16 is not extended to the channel side of the n⁺ source layer 14. For example, the depth of the shallowest part in the p⁺ carrier extraction layer 16 from the major surface 12a along the Z direction is deeper than the deepest position of the channel from the major surface 12a along the Z direction. Accordingly, although the p⁺ carrier extraction layer 16 is provided, the threshold value in the transistor action is not affected.

### Second Embodiment

Next, a manufacturing method of a semiconductor device according to a second embodiment will be explained.

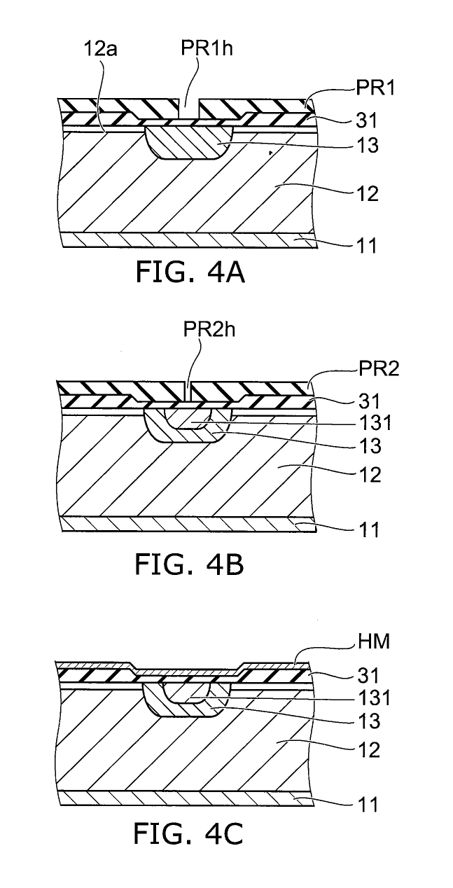

FIGS. 4A to 7B are schematic diagrams sequentially explaining the manufacturing method of the semiconductor device according to the second embodiment.

First, after the termination region B has been formed so as to provide a desired withstand voltage for the semiconductor device 110, the n-type drift layer 12 is formed on the n⁺ buffer layer 11 as shown in FIG. 4A. Next, after the gate insulating film 31 has been formed over the major surface 12a of the n-type drift layer 12, resist PR1 is coated. Then, by means of photolithography, an opening PR1h is formed in the resist PR1 at a position corresponding to a position approximately in the center of a part where the p-type base layer 13 is to be formed. In this state, B (boron) or the like is injected into the n-type drift layer 12 via the gate insulating film 31 from the opening PR1h of the resist PR1. Then, when thermal diffusion or the like is provided, the injected impurities (boron) are diffused and the p-type base layer 13 is formed. The p-type base layer 13 is formed selectively in the major surface 12a of the n-type drift layer 12. After that, the resist PR1 is peeled off.

Next, as shown in FIG. 4B, resist PR2 is coated and an opening PR2h is formed at a position corresponding to the central part of the p-type base layer 13 by means of the photolithography. In this state, B (boron) or the like is injected via the opening PR2h of the resist PR2. Then, when the thermal diffusion or the like is provided, the injected impurities (boron) are diffused and the p⁺ layer 131 is formed selectively in the central part of the p-type base layer 13. After that, the resist PR2 is peeled off.

Next, as shown in FIG. 4C, a hard mask HM is formed on the gate insulating film 31 by means of CVD (Chemical Vapor Deposition), for example. A silicon oxide film or a silicon nitride film, for example, is used for the hard mask HM.

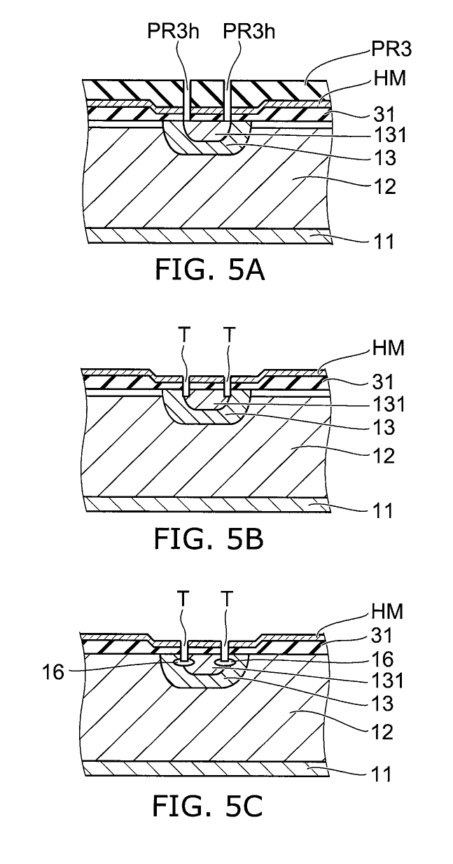

Next, as shown in FIG. 5A, resist PR3 is coated on the hard mask HM. The resist PR3 is used for forming an opening in the hard mask HM. After the resist PR3 has been coated, an opening PR3h is formed at a position corresponding to a position where a trench T to be described below is to be formed. Then, RIE (Reactive Ion Etching) is provided via the opening PR3h of this resist PR3 and the opening HMh is formed in the gate insulating film 31 and the hard mask HM.

Next, after the resist PR3 has been peeled off, as shown In FIG. 5B, the RIE, for example, is provided via the opening HMh in the hard mask HM, and the trench T is formed in the p⁺ layer 131. The trench T is engraved in a direction from the surface of the gate insulating film 31 toward the p⁺ layer 131 (Z direction). The trench T is provided down to a position deeper than the depth of the channel, for example.

Next, as shown in FIG. 5C, B (boron), for example, is injected via the trench T. As a result, in the p-type base layer 13 and the p⁺ layer 131 which contact the bottom part of the trench T, the p⁺ carrier extraction layer 16 having a higher concentration than these layers is formed. The p⁺ carrier extraction layer 16 is formed by the ion injection via the trench T and thus, spreads from the center of the bottom part of the trench T to be formed at an accurate position.

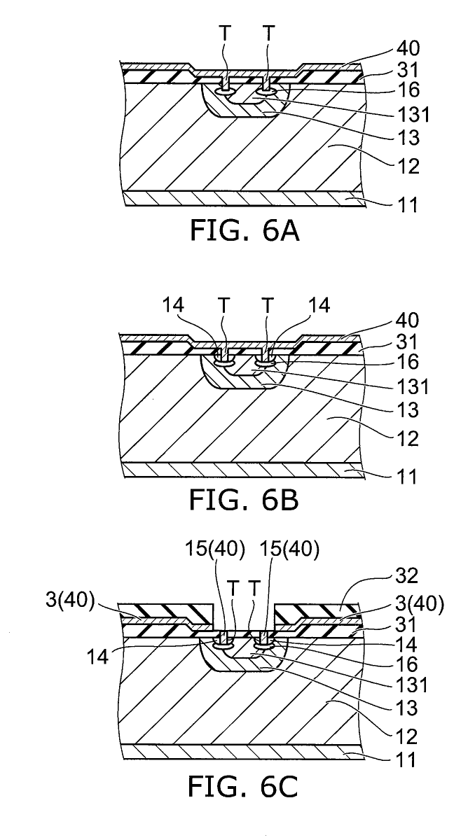

Next, after the removal of the hard mask HM, as shown in FIG. 6A, a poly-silicon 40 is formed by means of CVD, for example. The poly-silicon 40 is deposited on the gate insulating film 31 and also embedded inside the trench T.

Next, P (phosphorus), for example, is injected into the poly-silicon 40 and diffused to thereby provide conductivity thereto. At this time, as shown in FIG. 6B, P (phosphorus) is diffused into the p-type base layer 13 and the p⁺ layer 131 via the poly-silicon 40 embedded in the trench T. As a result, the n⁺ source layer 14 is formed on both sides by centering on the trench T. The n⁺ source layer 14 is formed between the p⁺ carrier extraction layer 16 and the surfaces of the p-type base layer 13 and the p⁺ layer 131. That is, the p⁺ carrier extraction layer 16 comes to have a state of contacting the bottom part of the n⁺ source layer 14. Further, the n⁺ source layer 14 is provided on both sides of the trench T and comes to a state of being provided in contact with the channel only on one of these sides.

Next, as shown in FIG. 6C, the poly-silicon 40 is etched at a predetermined position to be separated. In an example shown in FIG. 6C, the poly-silicon 40 on the gate insulating film 31 and the poly-silicon 40 in the trench T are separated from each other. The separated poly-silicon 40 on the gate insulating film 31 becomes the gate electrode 3. In contrast to this, the separated poly-silicon 40 in the trench T becomes the high-concentration n-type embedded layer 15. That is, the gate electrode 3 and the high-concentration n-type embedded layer 15 are formed by the same poly-silicon 40 in the same manufacturing process. Then, by the succeeding separation of the poly-silicon 40, each of the gate electrode 3 and the high-concentration n-type embedded layer 15 is configured.

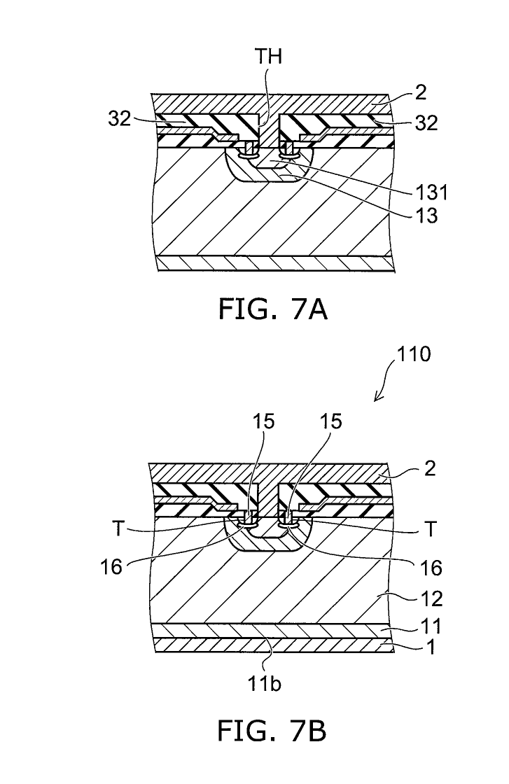

Next, as shown in FIG. 7A, the interlayer insulating film 32 is formed on the gate electrode 3, and a through-hole TH is formed at the position of p⁺ layer 131. Then, the source electrode 2 is formed on the whole surface. Aluminum, for example, is used as the source electrode 2. The source electrode 2 is formed on the interlayer insulating film 32 and also connected to the p⁺ layer 131 via the through-hole TH. As a result, the source electrode 2 is electrically connected to the p-type base layer 13 via the p⁺ layer 131.

Next, as shown in FIG. 7B, the drain electrode 1 is formed so as to contact the other major surface 11b of the n-type buffer layer 11. As a result, the semiconductor device 110 is completed.

In such a manufacturing method, by the impurity injection via the trench T, the p⁺ carrier extraction layer 16 is formed in the bottom part of the trench T and the n⁺ source layers 14 are formed on both sides by centering on the trench T. Because of this, it becomes possible to form the p⁺ carrier extraction layer 16 and the n⁺ source layer 14 at an accurate position based on the trench T, respectively.

In the semiconductor device 110 produced in this manner, the p⁺ carrier extraction layer 16 is provided in contact with the bottom part of the high-concentration n-type embedded layer 15 within the trench T and thus, it is possible to reduce the base resistance directly under the n⁺ source layer 14. As a result, a hole current path is formed when a large current flows and the increase in the base potential is suppressed. Accordingly, the latch-up withstand strength is improved in the semiconductor device 110.

Further, the p⁺ carrier extraction layer 16 is provided at a position apart from the channel formed in the p-type base layer 13. That is, the p⁺ carrier extraction layer 16 is not extended to the channel side of the n⁺ source layer 14. Accordingly, although the p⁺ carrier extraction layer 16 is provided, the threshold value of the transistor action is not affected.

### Third Embodiment

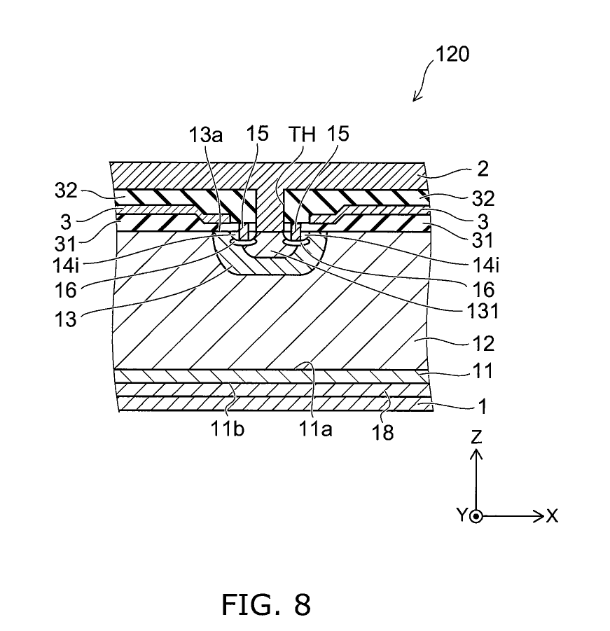

FIG. 8 is a schematic cross-sectional view illustrating a configuration of a semiconductor device according to a third embodiment.

As shown in FIG. 8, the semiconductor device 120 according to the embodiment functions as an IGBT (Insulated Bipolar Transistor).

The semiconductor device 120 is provided with an n⁺ buffer layer (first semiconductor region) 11, an n-type drift layer (second semiconductor region) 12, a collector electrode (first major electrode) 1i, a p-type base layer (third semiconductor region) 13, an n⁺ emitter layer (fourth semiconductor region) 14i, a p-type collector layer (seventh semiconductor region) 18, an emitter electrode 2i, a gate electrode (control electrode) 3, a high-concentration n-type embedded layer (fifth semiconductor region) 15, and a p⁺ carrier extraction layer (sixth semiconductor region) 16.

The p-type collector layer 18 is provided on the other major surface 11b of the n⁺ buffer layer 11. That is, the p-type collector layer 18 is provided between the n⁺ buffer layer 11 and the collector electrode 1i.

A major surface 13a of the p-type base layer 13 is selectively provided with the p⁺ layer 131. The p⁺ layer 131 is provided in the central part of the p-type base layer 13. Each of the p-type base layers 13 on both outsides of this p⁺ layer 131 becomes a channel.

The major surface 13a of the p-type base layer 13 is selectively provided with the n⁺ emitter layer 14i. The two n⁺ emitter layers 14i illustrated in FIG. 8 are provided at both end parts of the p⁺ layer 131 in the p-type base layer 13, respectively. That is, the two n⁺ emitter layers 14i are provided along the both end parts of the p⁺ layer 131, respectively. As a result, each of the n⁺ emitter layers 14i provided on both side of the p⁺ layer 131 is provided so as to contact the channel only on one side. Furthermore, the p⁺ layer 131 is provided between the two n⁺ emitter layers 14i. The emitter electrode 2i to be described below is connected to the p⁺ layer 131 disposed between the two n⁺ emitter layers 14i.

The gate electrode 3 is provided via a gate insulating film 31 which covers the p-type base layer 13, the n⁺ emitter layer 14i, and the n-type drift layer 12. FIG. 8 illustrates the neighboring two gate electrodes 3. Each of the gate electrodes 3 is disposed over the p-type base layer 13 between the n⁺ emitter layer 14i and the n-type drift layer 12. As a result, the p-type base layer 13 in this part functions as the channel. Here, each of the gate electrodes 3 has the same potential electrically.

The emitter electrode 2i is provided on the gate electrode 3 via an interlayer insulating film 32. The emitter electrode 2i is connected to the p-type base layer 13 between the two n⁺ emitter layers 14i via a through-hole TH provided between the two gate electrodes 3.

The high-concentration n-type embedded layer 15 is provided passing through in the Z direction in the central part of each of the n⁺ emitter layers 14i. The high-concentration n-type embedded layer 15 may be provided so as to pass through from the surface of the gate insulating film 31 to the bottom part of the n⁺ source layer 14.

Further, the p-type base layer 13 contacting the bottom part of the n⁺ emitter layer 14i is provided with the p⁺ carrier extraction layer 16. The impurity concentration of the p⁺ carrier extraction layer 16 is higher than that of the p-type base layer 13.

By providing such a p⁺ carrier extraction layer 16, it is possible to reduce a base resistance directly under the n⁺ emitter layer 14i. As a result, a hole current path is formed when a large current flows and the rise in the base potential is suppressed. Accordingly, the latch-up withstand strength is improved in the semiconductor device 120.

Further, the p⁺ carrier extraction layer 16 is disposed at a position apart from the channel formed in the p-type base layer 13. That is, the p⁺ carrier extraction layer 16 is not extended to the channel side of the n⁺ emitter layer 14i. Accordingly, although the p⁺ carrier extraction layer 16 is provided, the threshold value in the transistor action is not affected.

### Fourth Embodiment

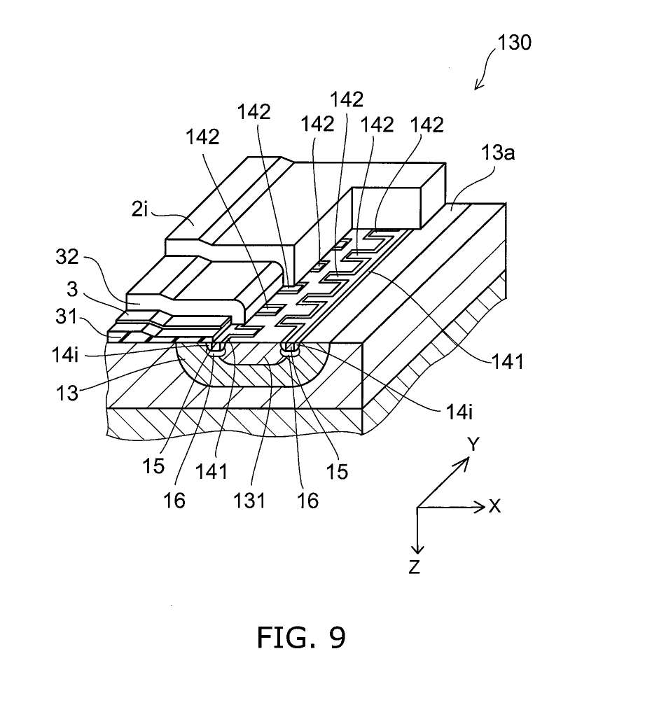

FIG. 9 is a schematic perspective view illustrating a configuration of a semiconductor device according to a fourth embodiment.

The semiconductor device 130 according to the embodiment which is shown in FIG. 9 functions as an IGBT.

Here, FIG. 9 illustrates a configuration on the upper side of an n-type drift layer 12.

In the semiconductor device 130 according to the embodiment, each of plural emitter layers 14i forms a comb shape when viewed along a major surface 13a of a p-type base layer 13 (X-Y plane). Further, between the neighboring n⁺ emitter layers 14i, teeth of the comb shapes face each other and are disposed alternately.

The n⁺ emitter layer 14i includes an extension part 141 extended along the Y direction and plural extension parts 142 extended from the extension part 141 along the X direction. The plural extension parts 142 are disposed at a predetermined interval along the Y direction. Since the plural extension parts 142 are extended from the extension part 141 to one side, the n⁺ emitter layer 14i has a comb shape along the major surface 13a (X-Y plane).

Between the neighboring n⁺ emitter layers 14i, the plural extension parts 142 are disposed so as to face each other. Additionally, the extension parts 142 facing each other is disposed so as to be extended toward the gaps between the extension parts 142 on the opposite side, respectively. That is, the extension parts 142 facing each other are disposed alternately.

The high-concentration n-type embedded layer 15, which is provided by passing through the central part of the n⁺ emitter layer 14i, has a comb shape with correspondence to the shape of the n⁺ emitter layer 14i. The emitter electrode 2i contacts the n⁺ emitter layer 14i, the high-concentration n-type embedded layer 15, and the p⁺ layer 131.

Since each of the neighboring n⁺ emitter layers 14i has a comb shape and the teeth of the comb face each other and are disposed alternately, the n⁺ emitter layer 14i can come to obtain a good contact with the emitter electrode 2i.

In the semiconductor device 130, it is possible to reduce the base resistance directly under the n⁺ emitter layer 14i, by providing a p⁺ carrier extraction layer 16. As a result, a hole current path is formed when a large current flows, and the rise in the base potential is suppressed. Accordingly, the latch-up withstand strength is improved in the semiconductor device 130.

Further, the p⁺ carrier extraction layer 16 is provided at a position apart from a channel formed in the p-type base layer 13. That is, the p⁺ carrier extraction layer 16 is not extended to the channel side of the n⁺ emitter layer 14. Accordingly, even if the p⁺ carrier extraction layer 16 is provided, the threshold value of the transistor action is not affected.

Note that, while FIG. 9 shows the semiconductor device 130 illustrating a configuration of an IGBT, the embodiment can be applied also to a configuration of a MOS transistor. In the configuration of the MOS transistor, the n⁺ emitter layer 14i becomes an n⁺ source layer 14, and the emitter electrode 2i becomes a source electrode 2. Further, the p-type collector layer 18 which is not shown in the drawing is not necessary in the MOS transistor. In a semiconductor device 130 as the MOS transistor, this n⁺ source layer 14 has the comb shape illustrated in FIG. 9.

### Fifth Embodiment

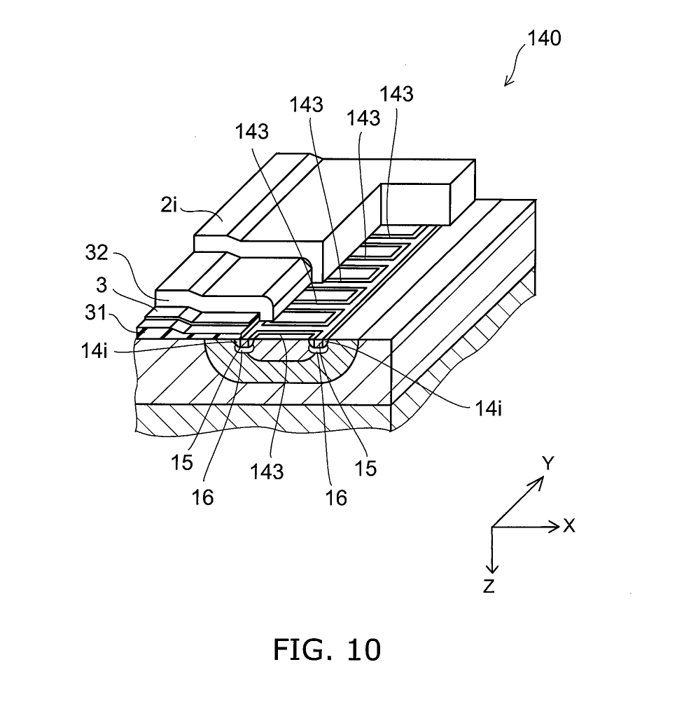

FIG. 10 is a schematic perspective view illustrating a configuration of a semiconductor device according to a fifth embodiment.

The semiconductor device 140 according to the embodiment which is shown in FIG. 10 functions as an IGBT.

Here, FIG. 10 illustrates the configuration on the upper side of an n-type drift layer 12.

In the semiconductor device 140 according to the embodiment, an n-type connection region 143 is provided connecting two neighboring n⁺ emitter layers 14i with each other.

The n⁺ emitter layer 14i is provided in the form of a stripe shape extended along the Y-direction. Further, the connection region 143 is provided connecting the two neighboring n⁺ emitter layers 14i with each other. The connection region 143 has the same conductivity type as the n⁺ emitter layer 14i. The plural connection regions 143 are disposed at a predetermined interval along the Y direction.

A high-concentration n-type embedded layer 15, which is provided by passing through the central part of the n⁺ emitter layer 14i, is provided also in the connection region 143. An emitter electrode 2i contacts the n⁺ emitter layer 14i, the connection region 143, the high-concentration n-type embedded later 15, and a p⁺ layer 13i.

The connection region 143 is provided between the two neighboring n⁺ emitter layers 14i, and thus a good contact with the emitter electrode 2i can be obtained.

In the semiconductor device 140, it is possible to reduce the base resistance directly under the n⁺ emitter layer 14i, by providing a p⁺ carrier extraction layer 16. As a result, a hole current path is formed when a large current flows, and the rise in the base potential is suppressed. Accordingly, the latch-up withstand strength is improved in the semiconductor device 140.

Furthermore, the p⁺ carrier extraction layer 16 is provided at a position apart from a channel formed in a p-type base layer 13. That is, the p⁺ carrier extraction layer 16 is not extended to the channel side of the n⁺ source layer 14. Accordingly, although the p⁺ carrier extraction layer 16 is provided, the threshold value of the transistor action is not affected.

Note that, while FIG. 10 shows the semiconductor device 140 illustrating a configuration of an IGBT, the embodiment can be applied also to a configuration of a MOS transistor. In the configuration of the MOS transistor, the n⁺ emitter layer 14i becomes an n⁺ source layer 14, and the emitter electrode 2i becomes a source electrode 2. A semiconductor device 140 as the MOS transistor has a configuration in which a connection region 143 is provided between the two neighboring n⁺ source layers 14.

According to the embodiments described above, the high-concentration carrier extraction layer can be selectively introduced directly under the source region (emitter region) and it becomes possible to suppress the parasitic transistor action without changing the threshold value of the transistor action.

While the embodiments have been explained hereinabove, embodiments are not limited to these examples. For example, the addition, deletion, and design change of the constituent and a combination of the features in each of the embodiments, which are carried out by those skilled in the art with respect to each of the above described embodiments, also fall within the range of the invention as far as the spirit of the invention is provided thereto.

For example, while the first conductivity type and the second conductivity type have been explained as being the n-type and the p-type, respectively, in each of the above described embodiments, the embodiments can be also carried out even if the first conductivity type and the second conductivity type are the p-type and the n-type, respectively.

Moreover, while each of the above described embodiments have been explained by centering on the structure of the cell region A, the structure of the termination region B is not limited particularly and can be carried out in various structures such as a field plate structure and a RESURF structure.

Still further, while the example using silicon (Si) as a semiconductor has been explained in each of the above described embodiments, a compound semiconductor such as silicon carbide (SiC) and Gallium nitride (GaN) or a wide band-gap semiconductor such as diamond can be also used as the semiconductor.

Still further, while the examples of the MOSFET and the IGBT have been explained in each of the above described embodiments, the embodiments can be applied also to a hybrid element of a MOSFET and an SBT (Schottky Barrier Diode), and a semiconductor device such as a reverse-conductivity type IGBT and an IEGT (Injection Enhanced Gate Transistor), for example.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A semiconductor device, comprising:
a first semiconductor region of a first conductivity type;
a second semiconductor region of the first conductivity type provided on a first major surface of the first semiconductor region;
a first major electrode provided on a second major surface side of the first semiconductor region, the second major surface being opposite to the first major surface;
a third semiconductor region of a second conductivity type provided in a part of a third major surface of the second semiconductor region, the third major surface being opposite to the first semiconductor region;
a fourth semiconductor region of the first conductivity type provided in a part of a fourth major surface of the third semiconductor region;
a second major electrode contacting the third semiconductor region and the fourth semiconductor region;
a control electrode provided via an insulating film which covers the third semiconductor region, the fourth semiconductor region, and the second semiconductor region;
a fifth semiconductor region of the first conductivity type provided passing through the fourth semiconductor region along a direction perpendicular to the fourth major surface of the third semiconductor region; and
a sixth semiconductor region of the second conductivity type provided in contact with a bottom part of the fourth semiconductor region, impurity concentration of the sixth semiconductor region being higher than impurity concentration of the third semiconductor region.

2. The device according to claim 1, wherein
only one of the fourth semiconductor regions provided on both sides of the fifth semiconductor region contacts a channel to be controlled by the control electrode.

3. The device according to claim 1, wherein
a depth of a shallowest part of the sixth semiconductor region from the third major surface of the second semiconductor region is deeper than a deepest position of a channel to be controlled by the control electrode from the third major surface of the second semiconductor region.

4. The device according to claim 1, wherein
a material of the fifth semiconductor region is the same as a material of the control electrode.

5. The device according to claim 1, further comprising
a seventh semiconductor region of the second conductivity type is provided between the first semiconductor region and the first major electrode.

6. The device according to claim 1, wherein
the sixth semiconductor region is extending from an end part of the fourth semiconductor region to the third semiconductor region.

7. The device according to claim 1, further comprising
a guard-ring electrode surrounding a peripheral of the control electrode.

8. The device according to claim 7, still further comprising
an equivalent-potential-ring electrode surrounding an outside of the guard-ring electrode.

9. The device according to claim 1, wherein
a plurality of the fourth semiconductor regions are provided,
each of the plurality of the fourth semiconductor regions is provided in a comb shape when viewed along the fourth major surface of the third semiconductor region, and
teeth of the comb shape face each other and disposed alternately between the two neighboring fourth semiconductor regions among the plural fourth semiconductor regions.

10. The device according to claim 9, wherein
a depth of a shallowest part of the sixth semiconductor region from the third major surface of the second semiconductor region is deeper than a deepest position of a channel to be controlled by the control electrode from the third major surface of the second semiconductor region.

11. The device according to claim 9, wherein
the sixth semiconductor region is extending from an end part of each of the fourth semiconductor regions to the third semiconductor region.

12. The device according to claim 1, wherein
the plural fourth semiconductor regions are provided,
each of the plural fourth semiconductor regions is formed in a stripe shape extended in a first direction along the fourth major surface of the third semiconductor region, and
plural connection regions having the first conductivity type and connecting the two neighboring fourth semiconductor regions among the plural fourth semiconductor regions are disposed along the first direction.

13. The device according to claim 12, wherein
a depth of a shallowest part of the sixth semiconductor region from the third major surface of the second semiconductor region is deeper than a deepest position of a channel to be controlled by the control electrode from the third major surface of the second semiconductor region.

14. The device according to claim 12, wherein
the sixth semiconductor region is extending from an end part of each of the fourth semiconductor regions to the third

15. A manufacturing method of a semiconductor device, comprising:
forming a first semiconductor region of a first conductivity type;
forming a second semiconductor region of the first conductivity type on a first major surface of the first semiconductor region;
forming an insulating film in a third major surface of the second semiconductor region, the third major surface being opposite to the first semiconductor region;
introducing impurities via the insulating film and forming a third semiconductor region of a second conductivity type selectively in the third major surface of the second semiconductor region;
forming a groove in the insulating film and the third semiconductor region in a direction perpendicular to the third major surface of the second semiconductor region;
introducing impurities into the third semiconductor region via the groove and forming a sixth semiconductor region having a higher impurity concentration than the third semiconductor region so as to cause the sixth semiconductor region to contact a bottom part of the groove;
forming a semiconductor layer on the groove and the insulating film, and then introducing impurities into the semiconductor layer to provide conductivity thereto and also forming a fourth semiconductor region of the first conductivity type in the third semiconductor region neighboring the groove;
separating the semiconductor layer on the insulating film and the semiconductor layer within the groove from each other and forming the semiconductor layer on the insulating film as a control electrode and forming the semiconductor layer within the groove as a fifth semiconductor region of the first conductivity type;
forming a first major electrode on a second major surface side of the first semiconductor region, the second major surface being opposite to the first major surface; and
connecting a second major electrode to the third semiconductor region and the fourth semiconductor region.

16. The method according to claim 15, wherein
the groove is formed to be deeper than a depth of a channel formed on a surface side of the third semiconductor layer.
